(19) United States
(12) Patent Application Publication
(10) Pub. No.: US 2002/0106865 A1
(43) Pub. Date: Aug. 8, 2002

(54) Method of forming shallow trench isolation

(76) Inventors: Tai-Ju Chen, Tainan (TW); Chien-Hsing Lin, Taichung (TW)

Correspondence Address: J C Patents Inc, 4 Venture, Suite 250, Irvine, CA, 92618, US

(21) Appl. No.: 09/812,200

(22) Filed: Mar. 19, 2001

(30) Foreign Application Priority Data
Feb. 5, 2001 (TW) 90102335

(51) Int. Cl. H01L 21/20; H01L 21/76; H01L 21/36

(52) U.S. Cl. 438/424; 438/296; 438/497

(57) ABSTRACT

A method of forming a shallow trench isolation (STI) structure. A pad oxide layer and a cap layer are sequentially formed over a substrate. The pad oxide layer, the cap layer and the substrate are patterned to form a trench. Oxide material is deposited into the trench to form a first oxide layer. The cap layer is removed to expose a portion of the first oxide layer. The pad oxide layer is removed. A selective liquid phase deposition is conducted to form a second oxide layer around the exposed first oxide layer.

### CROSS-REFERENCE TO RELATED APPLICATION

This application claims the priority benefit of Taiwan application serial no. 90102335, filed Feb. 5, 2001.

### BACKGROUND OF THE INVENTION

1. Field of Invention

The present invention relates to a method of manufacturing an integrated circuit. More particularly, the present invention relates to a method of forming a shallow trench isolation (STI) structure.

2. Description of Related Art

In general, an integrated circuit consists of a plurality of transistors. To prevent neighboring transistors from short-circuiting, device isolating regions must be formed. Typically, device isolation regions are formed in dense semiconductor circuits, for example, between neighboring field effect transistors (FET) inside a dynamic random access memory (DRAM). Each device isolation region effectively minimizes any charge leakage from the field effect transistor.

Shallow trench isolation (STI) is a technique of forming a device isolation region between neighboring field effect devices. The method includes forming a trench in a semiconductor substrate by performing an anisotropic etching and then depositing oxide material to fill the trench. Since the device isolation region formed by the STI technique has scaleable characteristics and produces no bird's beak encroachment as in a conventional local oxidation of silicon (LOCOS) method, the STI technique is ideal for isolating sub-micron metal-oxide-semiconductor (MOS) devices.

The conventional method of forming a shallow trench isolation (STI) region includes several steps. First, a substrate having a pad oxide layer and a cap layer thereon is provided. A trench is formed in the substrate and then an oxide material is deposited over the cap layer to fill the trench. The oxide layer is planarized by chemical-mechanical polishing and finally the cap layer is removed by etching. In the fabrication of an STI structure, an acid solution is likely to be employed in subsequent processing. The edges of the oxide layer are often attacked by the acid, leading to poor isolating effects. To alleviate the problem, spacers are conventionally formed on the sidewalls of the oxide layer after removing the cap layer. However, after the planarization of the oxide layer by chemical-mechanical polishing, the STI regions near the edges of the wafer and the STI regions near the center of the wafer are often at different height levels. Consequently, spacers of different thickness are produced. In addition, some STI regions may be so low that no spacer is able to form on the sidewalls after polishing. Under such circumstances, the edges of the oxide layer are no longer protected against acid attack.

### SUMMARY OF THE INVENTION

Accordingly, one object of the present invention is to provide a method of forming a shallow trench isolation (STI) structure. The method includes depositing a first oxide layer into a substrate trench and then performing a selective liquid phase deposition to form a second oxide layer around the exposed first oxide layer. The method produces a uniform second oxide layer around the first oxide layer so that the first oxide layer is protected against any subsequent acid attack even if chemical-mechanical polishing produces STI regions of variable heights. Detailed description of selective liquid phase deposition can be found in Tetsuya Homma, Takuya Katoh, Yoshiaki Yamada, and Yukinobu Murao, J. Electrochem. Soc., Vol. 140, No. 8, p2410 ˜p2414, 1993.

To achieve these and other advantages and in accordance with the purpose of the invention, as embodied and broadly described herein, the invention provides a method of forming a shallow trench isolation (STI) structure. A pad oxide layer and a cap layer are sequentially formed over a substrate. The pad oxide layer, the cap layer and the substrate are patterned to form a trench. Oxide material is deposited into the trench to form a first oxide layer. The cap layer is removed to expose a portion of the first oxide layer. The pad oxide layer is next removed. A selective liquid phase deposition is conducted to form a second oxide layer around the exposed first oxide layer.

In selective liquid phase deposition, the second oxide layer is only formed over the exposed portion of the first oxide layer. No oxide material is deposited over the exposed substrate. Hence, unlike the conventional method of forming spacers, this invention requires no etching back of the deposited oxide material and fabrication is greatly simplified.

In addition, the second oxide layer formed by selective liquid phase deposition has a uniform thickness. Thus, the method of this invention eliminates the problem of producing spacers of variable thickness that results from the variable height STI structures created after chemical-mechanical polishing in a conventional process. Moreover, even if the STI structure is exceedingly short, uniformly thick spacers can be readily formed over the sidewalls of the oxide layer.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the progression of steps for forming a shallow trench isolation structure on a substrate according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

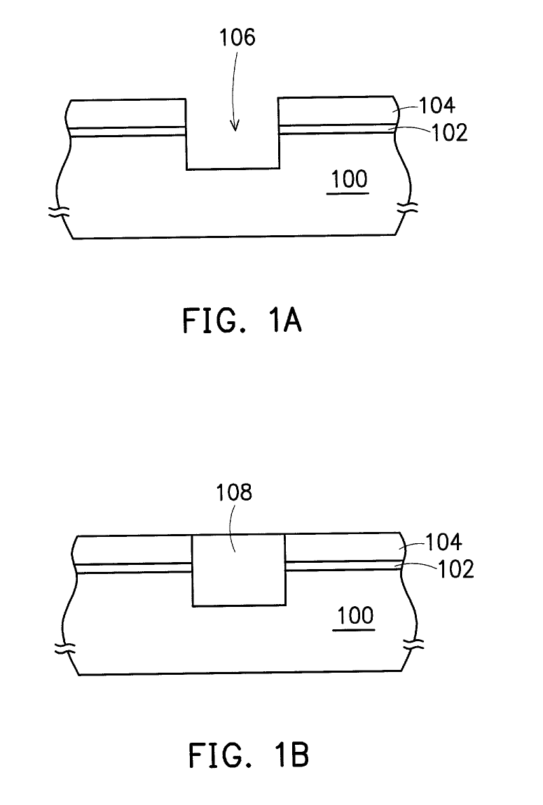

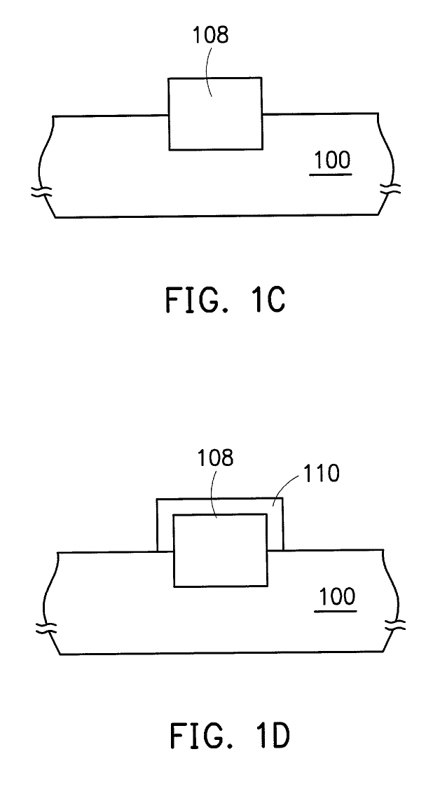

FIGS. 1A through 1D are schematic cross-sectional views showing the progression of steps for forming a shallow trench isolation structure on a substrate according to one preferred embodiment of this invention.

As shown in FIG. 1A, a substrate 100 is provided. A pad oxide layer 102 and a cap layer 104 are sequentially formed over the substrate 100. The pad oxide layer 102 having a thickness between 90 Å to 130 Å can be formed, for example, by thermal oxidation. The cap layer 104 can be a silicon nitride layer formed, for example, by chemical vapor deposition. The cap layer 104, the pad oxide layer 102 and the substrate 100 are patterned to form a trench 106. The trench is formed, for example, by conducting photolithographic and etching processes.

As shown in FIG. 1B, oxide material is deposited into the trench 106 to form a first oxide layer 108. The first oxide layer 108 is formed, for example, by depositing oxide material into the trench 106 and over the cap layer 104 in chemical vapor deposition. Chemical-mechanical polishing is carried out to planarize the oxide layer and ultimately expose the cap layer 104.

As shown in FIG. 1C, the cap layer 104 is removed to expose a portion of the first oxide layer 108. The cap layer 104 is removed, for example, by wet etching. The cap layer 104 and the first oxide layer 108 are formed using different materials, for example, the cap layer 104 can be a silicon nitride layer while the first oxide layer 108 can be a silicon dioxide layer. Hence, an etchant with a high etching selectivity ratio between the two layers can be used to etch the cap layer 104 and form the protruding first oxide layer 108. The pad oxide layer 102 is also removed. The pad oxide layer 102 is removed, for example, by applying hydrofluoric acid to the substrate 100.

In the process of removing the cap layer 104, a portion of the pad oxide layer is also removed, thereby reducing the thickness of the pad oxide layer 102. Therefore, in the process of removing the pad oxide layer 102, only an insignificant portion of the first oxide layer 108 is removed. The major portion of the first oxide layer 108 remains exposed above the substrate 100.

As shown in FIG. 1D, a selective liquid phase deposition is conducted to form a second oxide layer 110 around the first oxide layer 108. The second oxide layer 110 having a thickness between 450 Å to 550 Å is formed by immersing the substrate 100 into a reactant solution at a temperature between 18° C. to 40° C. The reactant solution is prepared by mixing an over-saturated fluorosilicic acid (H₂SiF₆) with water in a ratio of between 6:1 to 3:1, wherein the over-saturated fluorosilicic acid is prepared by adding powdered silicon dioxide into the fluorosilicic acid having a concentration of 40%. So, when the substrate 100 is immersed in the reactant solution, silicon dioxide that elutes from the reactant solution is deposited as the second oxide layer 110 on the substrate 100.

Because the reaction rate with the substrate 100 is much slower than the reaction rate with the first oxide layer 108 in a selective liquid phase deposition, oxide material is deposited around the first oxide layer 108, to form the second oxide layer 110, while none is deposited over the substrate 100. The second oxide layer 110 serves as spacers to shield the first oxide layer 108 against acid attack in subsequent etching processes. Moreover, unlike the conventional process in which the spacer thickness depends on the height of the STI structure, the second oxide layer 110 has a relatively constant thickness.

By performing a selective liquid phase deposition, the second oxide layer is formed over the exposed portion of the first oxide layer only. No oxide material is deposited over the exposed substrate. Hence, unlike the conventional method of forming spacers, this invention requires no etching back of the deposited oxide material and fabrication is greatly simplified.

In addition, the second oxide layer formed by selective liquid phase deposition has a uniform thickness. Thus, the method of this invention eliminates the problem of producing spacers of variable thickness that results from the variable height STI structures created after chemical-mechanical polishing in a conventional process. Moreover, even if the STI structure is exceedingly short, uniformly thick spacers can be readily formed over the sidewalls of the oxide layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a shallow trench isolation structure, comprising the steps of:
providing a substrate;
forming a pad oxide layer over the substrate;
forming a cap layer over the pad oxide layer;
patterning the cap layer, the pad oxide layer and the substrate to form a trench;
depositing oxide material into the trench to form a first oxide layer;
removing the cap layer to expose a portion of the first oxide layer;
removing the pad oxide layer; and
forming a second oxide layer surrounding the exposed first oxide layer by conducting a selective liquid phase deposition.

2. The method of claim 1, wherein the selective liquid phase deposition to form the second oxide layer is conducted at a temperature between about 18° C. to 40° C.

3. The method of claim 1, wherein the step of forming the second oxide layer by selective liquid phase deposition includes immersing the substrate into a reaction solution.

4. The method of claim 3, wherein the reaction solution is prepared by mixing a over-saturated fluorosilicic acid solution with water with a ratio of between 6:1 to 3:1.

5. The method of claim 4, wherein the over-saturated fluorosilicic acid solution is prepared by adding powdered silicon dioxide into a fluorosilicic acid having a concentration of 40%.

6. The method of claim 1, wherein the second oxide layer has a thickness between about 450 Å to 550 Å.

7. The method of claim 1, wherein the cap layer includes a silicon nitride layer.

8. The method of claim 1, wherein the step of removing the pad oxide layer includes using hydrofluoric acid solution.

9. A method of forming a shallow trench isolation structure, comprising the steps of:
providing a substrate;
forming a pad oxide layer over the substrate;
forming a cap layer over the pad oxide layer;
patterning the cap layer, the pad oxide layer and the substrate to form a trench;
depositing oxide material into the trench to form a first oxide layer;
removing the cap layer to expose a portion of the first oxide layer;
removing the pad oxide layer; and
forming a second oxide layer surrounding the exposed first oxide layer.

10. The method of claim 9, wherein the step of forming the second oxide layer includes selective liquid phase deposition.

11. The method of claim 9, wherein the second oxide layer has a thickness between about 450 Å to 550 Å.

12. The method of claim 9, wherein the cap layer includes a silicon nitride layer.

13. The method of claim 9, wherein the step of removing the pad oxide layer includes using hydrofluoric acid solution.

14. A method of protecting a shallow trench isolation structure, comprising the steps of:
providing a shallow trench isolation structure; and
forming an oxide layer over the exposed surface of the shallow trench isolation structure by selective liquid phase deposition.

15. The method of claim 14, wherein the selective liquid phase deposition to form the second oxide layer is conducted at a temperature between about 18° C. to 40° C.

16. The method of claim 14, wherein the step of forming the second oxide layer by selective liquid phase deposition includes immersing the substrate into a reaction solution.

17. The method of claim 16, wherein the reaction solution is prepared by mixing an over-saturated fluorosilicic acid solution with water in a ratio of between 6:1 to 3:1.

18. The method of claim 17, wherein the over-saturated fluorosilicic acid solution is prepared by mixing a fluorosilicic acid having a concentration of 40% with powdered silicon dioxide.

19. The method of claim 14, wherein the second oxide layer has a thickness between about 450 Å to 550 Å.
